(19) United States
(12) Patent Application Publication
(10) Pub. No.: US 2011/0237063 A1
(43) Pub. Date: Sep. 29, 2011

(54) METHODS OF FABRICATING SEMICONDUCTOR DEVICE

(76) Inventors: Eungon KIM, Hwaseong-si (KR); Moonhan Park, Yongin-si (KR); Kwangyul Lee, Suwon-si (KR); CheolWoo Park, Hwaseong-si (KR); Sang Min Lee, Seoul (KR)

(21) Appl. No.: 13/070,051

(22) Filed: Mar. 23, 2011

(30) Foreign Application Priority Data
Mar. 24, 2010 (KR) 10-2010-0026430

(51) Int. Cl. H01L 21/3213

(52) U.S. Cl. 438/592; 257/E21.496

(57) ABSTRACT

A method of fabricating a semiconductor device includes forming a gate dielectric layer and a first gate layer sequentially on an overall surface of a substrate including a first region and a second region, forming a lanthanum-oxide (La₂O₃) mask pattern on the first gate layer disposed on the second region, and selectively removing the first gate layer disposed on the first region by etching using the La₂O₃ mask pattern as a mask, thereby forming a first gate layer pattern on the second region.

### BACKGROUND

1. Field

The present disclosure herein relates to methods of fabricating a semiconductor device, and more particularly, to methods of fabricating a semiconductor device using a lanthanum-oxide (La₂O₃) mask.

2. Description of the Related Art

In general, semiconductor memory devices are mainly classified into volatile memory devices and nonvolatile memory devices. Volatile memory devices lose stored data upon interruption of power. Volatile memory devices include a dynamic random access memory (DRAM) and a static RAM (SRAM). Nonvolatile memory devices do not lose stored data although power supply is interrupted. Nonvolatile memory devices include a programmable read only memory (PROM), an erasable PROM (EPROM), and an electrically EPROM (EEPROM), and a flash memory device.

Differently from the DRAM, an SRAM is a static device not requiring a refresh operation. An SRAM may differ from a DRAM in that an SRAM operates at a high speed while consuming low power. The SRAM is widely used in portable electronic devices such as a cache memory of a computer, a mobile phone, and the like.

### SUMMARY

According to an embodiment, there is provided a method of fabricating a semiconductor device, including forming a gate dielectric layer and a first gate layer sequentially on an overall surface of a substrate that comprises a first region and a second region, such that the gate dielectric layer and the first gate layer are disposed on the first region and the second region, forming a lanthanum-oxide (La₂O₃) mask pattern on the first gate layer disposed on the second region, and selectively removing the first gate layer disposed on the first region by etching using the La₂O₃ mask pattern as a mask, thereby forming a first gate layer pattern on the second region.

The method may further include removing the La₂O₃ mask pattern.

The removing of the La₂O₃ mask pattern may be performed by wet etching using hydrochloric acid (HCl) as an etching solution.

The method may further include forming a second gate layer on an overall surface of the substrate having the first gate layer pattern after the La₂O₃ mask pattern is removed, and patterning the second gate layer, the first gate layer pattern, and the gate dielectric layer.

The second gate layer may include polysilicon, a metal silicide, or a lamination of polysilicon and metal silicide deposited in sequence.

The forming of the La₂O₃ mask pattern on the first gate layer disposed on the second region may include forming a La₂O₃ mask layer on the first gate layer disposed on the first region and the second region, forming a photoresist pattern on the La₂O₃ mask layer to expose the La₂O₃ mask layer disposed on the first region, selectively removing the La₂O₃ mask layer disposed on the first region by etching, using the photoresist pattern as a mask, and removing the photoresist pattern.

The selective removing of the La₂O₃ mask layer disposed on the first region may be performed by dry etching.

The gate dielectric layer may include a high-k material.

The first gate layer may include a metal, a metal oxide, or a metal nitride.

The selective removing of the first gate layer disposed on the first region may be performed by wet etching using a first standard solution as an etching solution.

According to another embodiment, there is provided a method of fabricating a semiconductor device, including forming a gate dielectric layer on an overall surface of a substrate, forming a gate layer on the gate dielectric layer, forming a lanthanum-oxide (La₂O₃) mask pattern on the gate layer, and patterning the gate layer and the gate dielectric layer by etching using the La₂O₃ mask pattern as a mask, thereby forming a gate pattern.

The method may further include removing the La₂O₃ mask pattern.

The removing of the La₂O₃ mask pattern may be performed by wet etching using a hydrochloric acid (HCl) as an etching solution.

The forming of the La₂O₃ mask pattern on the gate layer may include forming a La₂O₃ mask layer on the gate layer, forming a photoresist pattern on the La₂O₃ mask layer to partially expose the La₂O₃ mask layer, selectively removing the exposed La₂O₃ mask layer by etching using the photoresist pattern as a mask, and removing the photoresist pattern.

The selective removing of the La₂O₃ mask layer may be performed by dry etching.

The gate dielectric layer may include a high-k material.

The forming of the gate layer may include forming a first gate layer on the gate dielectric layer, and forming a second gate layer on the first gate layer.

The first gate layer may include a metal, a metal oxide, or a metal nitride.

The second gate layer may include a polysilicon, a metal silicide, or a lamination of polysilicon and metal silicide deposited in sequence.

According to another embodiment, a semiconductor device structure includes a substrate, a gate dielectric layer on the substrate, a gate layer on the gate dielectric layer, and a lanthanum-oxide (La₂O₃) mask pattern on the gate layer.

The gate layer may be a patterned gate layer corresponding to the La₂O₃ mask pattern.

The substrate may include a first region and a second region, wherein the first region includes only the gate dielectric layer on the substrate, and the second region includes the gate dielectric layer, the patterned gate layer and the La₂O₃ mask pattern.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 through 7 illustrate process sectional views relating to a method of fabricating a semiconductor device according to an embodiment of the inventive concept;

FIG. 8 illustrates a block diagram schematically showing an exemplary memory system including the semiconductor device fabricated according to the embodiment;

FIG. 9 illustrates a block diagram schematically showing an exemplary memory card including the semiconductor device fabricated according to the embodiment; and

FIG. 10 illustrates a block diagram schematically showing an exemplary data processing system including the semiconductor device fabricated according to the embodiment.

### DETAILED DESCRIPTION

Korean Patent Application No. 10-2010-0026430, filed on Mar. 24, 2010, in the Korean Intellectual Property Office, and entitled: “Methods of Fabricating Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Like reference numerals refer to like elements throughout.

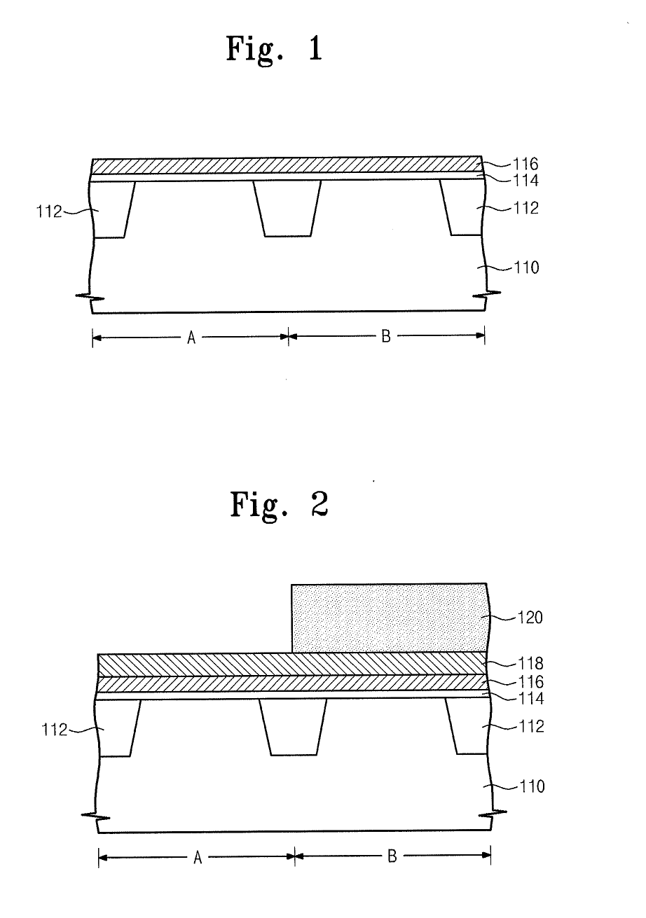

FIGS. 1 through 7 illustrate process sectional views relating to a method of fabricating a semiconductor device according to an embodiment of the inventive concept.

Referring to FIG. 1, a device isolation layer 112 defining a first region A and a second region B is formed on a substrate 110.

An N-type metal oxide semiconductor (NMOS) transistor may be formed in the first region A whereas a P-type MOS (PMOS) transistor may be formed in the second region B. According to an exemplary embodiment, an NMOS transistor and a PMOS transistor of a static random access memory (SRAM) memory device may be formed in the first region A and the second region B, respectively.

The substrate 110 may be a silicon substrate. In this case, silicon channels (not shown) having a predetermined depth from a surface of the substrate 110 may be formed in both the first and second regions A and B. The device isolation layer 112 may contain a silicon oxide (SiO₂).

A gate dielectric layer 114 is formed on the overall surface of the substrate 110. The gate dielectric layer 114 may include a high-k material. Herein, the term “high-k material” may refer to a material having a higher dielectric constant ‘k’ than SiO₂. Generally, a dielectric constant ‘k’ of the high-k material may be 10 or higher. The high-k material may include hafnium oxide (HfO₂), zirconium oxide (ZrO₂), titanium oxide (TiO₂), aluminum oxide (Al₂O₃), tantalum oxide (Ta₂O₅), cesium oxide (Ce₂O₃), zirconium silicon oxide (ZrSiO₄), zirconium silicon oxynitride (ZrSiON), hafnium silicon oxide (HfSiO₄), hafnium silicon oxynitride (HfSiON), hafnium aluminum oxide (HfAlO), hafnium aluminum oxynitride (HfAlON), aluminum silicon oxynitride (AlSiON), barium silicon oxide (BaSiO₄), lead silicon oxide (PbSiO₄), Ba—Sr—Ti (BST), or Pb—Zr—Ti (PZT). The gate dielectric layer 114 using such high-k materials may have a monolayer structure or a multilayer structure. Also, the gate dielectric layer 114 may be a combination of the above-mentioned high-k materials.

A first gate layer 116 is disposed on the gate dielectric layer 114. The first gate layer 116 may include a metal, a metal oxide, or a metal nitride. Examples of materials for the first gate layer 116 include titanium (Ti), tantalum (Ta), hafnium (HO, zirconium (Zr), aluminum (Al), copper (Cu), tungsten (W), molybdenum (Mo), platinum (Pt), ruthenium oxide (RuO), titanium nitride (TiN), tantalum nitride (TaN), hafnium nitride (MN), zirconium nitride (ZrN), tungsten nitride (WN), molybdenum nitride (MoN), titanium aluminum nitride (TiAlN), tantalum aluminum nitride (TaAlN), titanium silicon nitride (TiSiN), tantalum silicon nitride (TaSiN), and similar materials.

For example, to form a first gate layer 116 made of TiAlN, a TiN layer, an Al layer, and a TiN layer may be sequentially formed and then converted into the TiAlN through heat treatment.

Referring to FIG. 2, after a lanthanum-oxide (La₂O₃) mask layer 118 is formed on the first gate layer 116, a photoresist pattern 120 is formed on the La₂O₃ mask layer 118 such that the La₂O₃ mask layer 118 disposed on the first region A remains exposed.

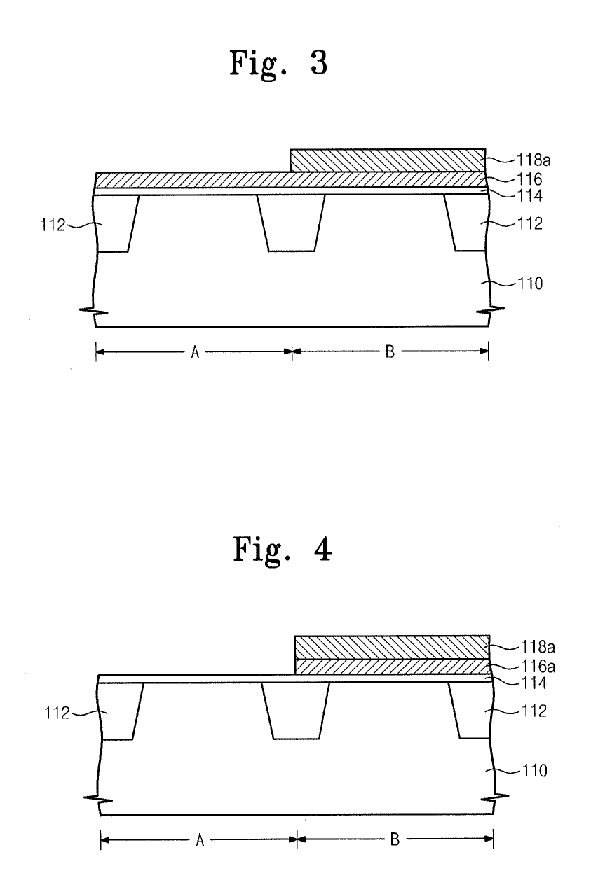

Referring to FIG. 3, etching is performed using the photoresist pattern 120 as a mask, thereby selectively removing the La₂O₃ mask layer 118 on the first region A. Here, dry etching may be used to selectively remove the La₂O₃ mask layer 118 from the first region A.

The photoresist pattern 120 is removed and, accordingly, a La₂O₃ mask pattern 118a may be formed on the first gate layer 116 disposed on the second region B.

If the semiconductor device formed according to the present embodiment is to be an SRAM memory device, a process of forming the La₂O₃ mask pattern 118a on the first gate layer 116 in the second region B may be a process for exposing a region to form an NMOS transistor of the SRAM memory device.

Referring to FIG. 4, etching is performed by using the La₂O₃ mask pattern 118a as a mask such that the first gate layer 116 on the first region A is selectively removed, thereby forming a first gate layer pattern 116a on the second region B.

Here, the selective removal of the first gate layer 116 from the first region A may be performed by wet etching, which uses a first standard solution as an etching solution. The first standard solution may be a standard cleaning solution (SC-1).

The standard cleaning solution SC-1 may contain ammonium hydroxide (NH₄OH), peroxide (H₂O₂) and water (H₂O) in the molar ratio of about 3-10:1:60-200.

When the first gate layer 116 is etched using the La₂O₃ mask pattern 118a, an After Develop Inspection (ADI)/After Cleaning Inspection (ACI) Critical Dimension (CD) skew may be reduced compared to in a typical etching process in which a mask constituted by a developable bottom anti-reflective coating (BARC) layer and a photoresist layer is used. The ADI/ACI CD skew is reduced because a profile of the developable BARC layer disposed on the first gate layer 116 made of the metal oxide or metal nitride is less stable than a profile of the La₂O₃ mask pattern 118a. Specifically, the La₂O₃ mask pattern 118a is capable of reducing the ADI/ACI CD skew by about 20 nm in comparison with the typical mask including the developable BARC layer. As a consequence, an ADI margin may increase.

Therefore, if the first gate pattern 116a were to be formed by etching the first gate layer 116 by using the developable BARC layer as a mask, a margin for forming the first gate pattern 116a may be insufficient. On the other hand, when the La₂O₃ mask pattern 118a is used as a mask in etching the first gate layer 116, the stable first gate pattern 116a may be obtained.

Referring to FIGS. 3-4, a semiconductor structure includes the substrate 110, the gate dielectric layer 114, the gate layer 116 (which may be the first gate pattern 116a), and the La₂O₃ mask pattern 118a. The first region A may include only the substrate and the gate dielectric layer 114, and the second region B may include the substrate 110, the gate dielectric layer 114, the first gate layer pattern 116a, and the La₂O₃ mask pattern 118a.

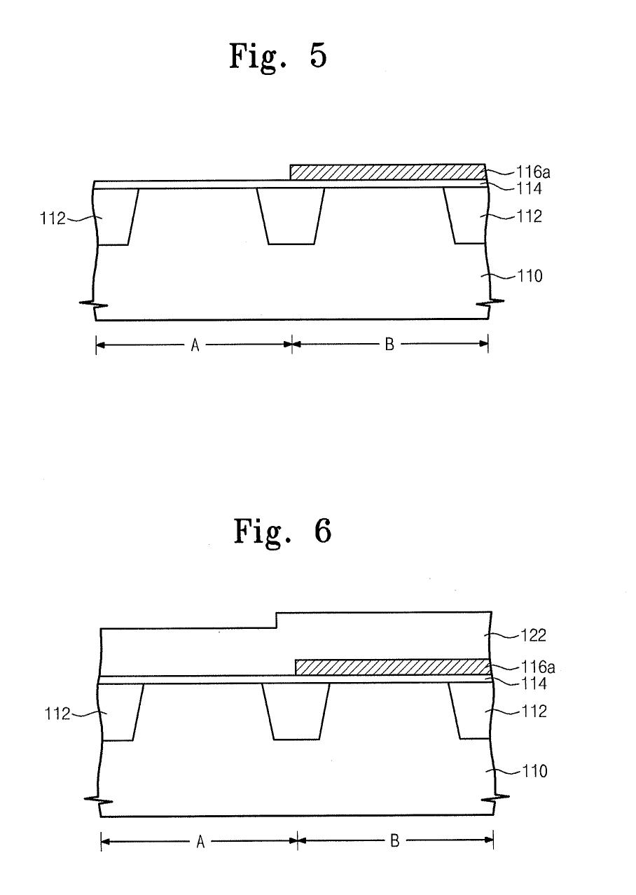

Referring to FIG. 5, the La₂O₃ mask pattern 118a is removed. Wet etching using a hydrochloric acid (HCl) solution as an etching solution may be used for the removal of the La₂O₃ mask pattern 118a.

Referring to FIG. 6, after the La₂O₃ mask pattern 118a is removed, a second gate layer 122 is formed on the overall surface of the substrate 110 including the first gate layer pattern 116a. The second gate layer 122 may include polysilicon or a metal silicide, or may be a lamination of the polysilicon and metal silicide deposited in sequence.

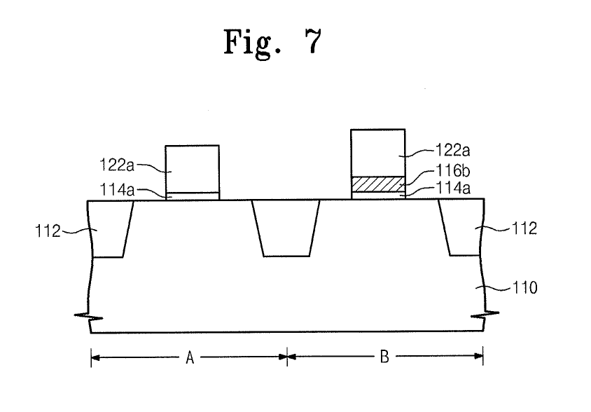

Referring to FIG. 7, the second gate layer 122, the first gate layer pattern 116a, and the gate dielectric layer 114 are patterned to thereby form gate patterns on the first region A and the second region B, respectively.

The gate patterns of the first region A may include a gate dielectric layer pattern 114a and the second gate layer pattern 122a sequentially deposited on the substrate 110. The gate patterns of the second region B may include the gate dielectric layer pattern 114a, the first gate layer pattern 116b, and the second gate layer pattern 122a sequentially deposited on the substrate 110.

Although not shown, source/drain regions may be formed on both sides of the gate patterns in the substrate 110 by an ion implantation process using the gate patterns as masks. For example, an NMOS transistor may be formed in the first region A while a PMOS transistor is formed in the second region B.

The semiconductor device according to the present embodiment may be a semiconductor memory device that includes a MOS transistor. When the semiconductor device is an SRAM memory device, since the NMOS transistor of the first region A and the PMOS transistor of the second region B have different gate patterns from each other, a difference of operational characteristics between the transistors may be minimized. Accordingly, the operational characteristics of the SRAM memory device may be optimized.

In the semiconductor device fabricated according to the embodiment of the inventive concept, since the metal gate layer is etched using the La₂O₃ mask, the ADI/ACI CD skew may be reduced compared to in a typical etching process in which a mask constituted by a developable BARC layer and a photoresist layer is used. As a result, the semiconductor device having stable gate patterns can be obtained.

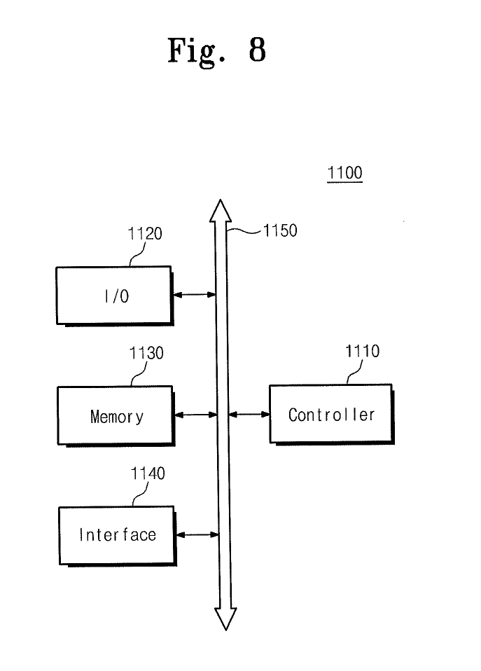

FIG. 8 is a block diagram schematically showing an exemplary memory system including the semiconductor device fabricated according to the embodiment.

Referring to FIG. 8, the memory system 1100 may be applied to a personal digital assistant (PDA), a portable computer, a web tablet, a wireless phone, a mobile phone, a digital music player, a memory card, or any other devices capable of wirelessly receiving and transmitting data.

The memory system 1100 includes a controller 1110, an input/output (I/O) unit 1120 such as a key pad, a key board, and a display device, a memory 1130, an interface 1140, and a bus 1150. The memory 1130 and the interface 1140 communicate with each other through the bus 1150.

The controller 1110 includes at least one microprocessor, a digital signal processor, a microcontroller, or other similar processors. The memory 1130 may store commands performed by the controller 1110. The I/O unit 1120 may receive or transmit data or signals between the system 1100 and the outside. For example, the I/O unit 1120 may include a key board, a key pad, or a display device.

The memory 1130 may include the semiconductor device fabricated according to the embodiment of the inventive concept.

In addition, the memory 1130 may further include a volatile memory which is accessible at any time, or various other types of memory.

The interface 1140 transmits data to a communication network or receives the data from the communication network.

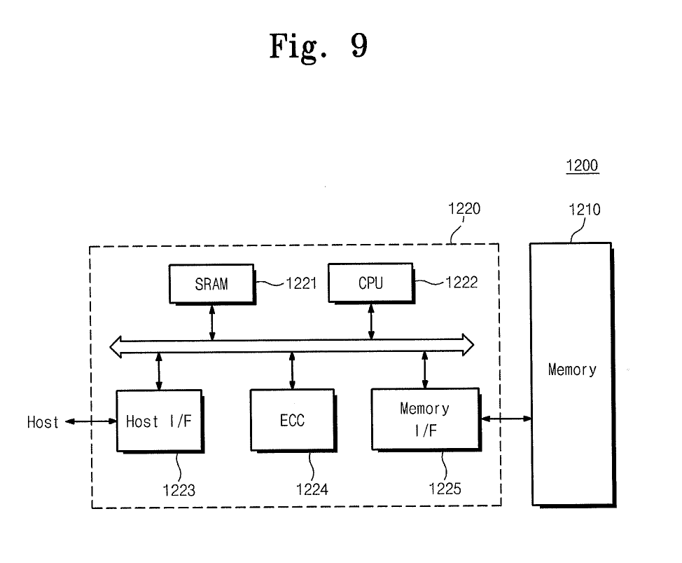

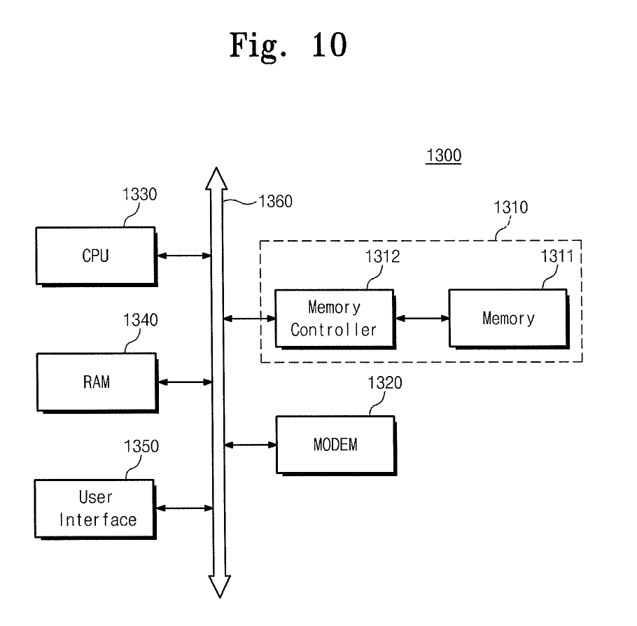

FIG. 9 is a block diagram schematically showing an exemplary memory card including the semiconductor device fabricated according to the embodiment.

Referring to FIG. 9, the memory card 1200 to support large-capacity data storage is equipped with a memory device 1210 including the semiconductor device fabricated according to the embodiment. The memory card 1200 according to the embodiment includes a memory controller 1220 adapted to control overall data exchange between a host and the memory device 1210.

An SRAM 1221 may also function as an operation memory of a central processing unit (CPU) 1222. The SRAM 1221 may be a semiconductor device fabricated according to the embodiment of the inventive concept. The host interface 1223 includes a data exchange protocol of the host connected with the memory card 1200. An error correction coding (ECC) block 1224 detects and corrects errors included in data read out by the memory device 1210 having multi-bit characteristics. A memory interface 1225 interfaces with the memory device 1210 which includes the semiconductor device fabricated according to the embodiment. The CPU 1222 controls the overall operations for data exchange with the memory controller 1220. Although not shown, the memory card 1200 may further include a read only memory (ROM) for storing coding data for interface with the host, and so forth.

Accordingly, a highly integrated memory system may be achieved by using the semiconductor device, the memory card, or the memory system fabricated in accordance with the embodiment of the inventive concept.

FIG. 10 is a block diagram schematically showing an exemplary data processing system including the semiconductor device fabricated according to the embodiment.

Referring to FIG. 10, a memory system 1310 includes a semiconductor device 1311 fabricated according to the embodiment of the inventive concept and a memory controller 1312 adapted to control overall data exchange between a system bus 1360 and the semiconductor device 1311. The memory system 1310 is mounted to the data processing system such as a mobile device and a desktop computer. The data processing system 1300 according to the embodiment includes the memory system 1310, and a modulator and demodulator (MODEM) 1320, a CPU 1330, a RAM 1340 and a user interface 1350 which are electrically connected to the system bus 1360. The memory system 1310 is configured substantially in the same manner as the memory system described with FIG. 8. The memory system 1310 stores data processed by the CPU 1330 or input from the outside. The memory system 1310 may include a solid state drive (SSD). In this case, the data processing system 1300 is capable of stably storing large-capacity data in the memory system 1310. As the reliability thus increases, resources required for error correction of the memory system 1310 are reduced, consequently enabling a high speed data exchange of the data processing system 1300. Although not shown, it should be understood by those skilled in the art that the data processing system 1300 may further include an application chipset, a camera image signal processor (ISP), and an I/O device.

Furthermore, the memory device or the memory system including the semiconductor device according to the embodiment may be mounted to various types of package. For example, the memory device or the memory system may be mounted on a package by being packaged into various types including a package on package (POP), Ball Grid Arrays (BGAs), Chip Scale Packages (CSPs), Plastic Leaded Chip Carrier (PLCC), Plastic Dual In-line Package (PDIP), die in waffle pack, die in wafer form, Chip On Board (COB), CERamic Dual In-line Package (CERDIP), plastic Metric Quad Flat Pack (MQFP), Thin Quad Flat Pack (TQFP), Small-Outline Integrated Circuit (SOIC), Shrink Small-Outline Package (S SOP), Thin Small-Outline Package (TSOP), Thin Quad Flat Pack (TQFP), System In Package (SIP), Multi Chip Package (MCP), Wafer-level Fabricated Package (WFP), and Wafer-level processed Stack Package (WSP).

According to the embodiment as described above, a metal gate layer is etched using a La₂O₃ mask. Therefore, after develop inspection (ADI)/after cleaning inspection (ACI), critical dimension (CD) skew may be reduced compared to in a typical etching process which uses a mask constituted by a developable bottom anti-reflective coating layer and a photoresist layer. As a result, a semiconductor device having more stable gate patterns may be fabricated.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of fabricating a semiconductor device, comprising:
forming a gate dielectric layer and a first gate layer sequentially on an overall surface of a substrate that comprises a first region and a second region, such that the gate dielectric layer and the first gate layer are disposed on the first region and the second region;
forming a lanthanum-oxide (La₂O₃) mask pattern on the first gate layer disposed on the second region; and
selectively removing the first gate layer disposed on the first region by etching using the La₂O₃ mask pattern as a mask, thereby forming a first gate layer pattern on the second region.

2. The method as claimed in claim 1, further comprising removing the La₂O₃ mask pattern.

3. The method as claimed in claim 2, wherein the removing of the La₂O₃ mask pattern is performed by wet etching using hydrochloric acid (HCl) as an etching solution.

4. The method as claimed in claim 2, further comprising:
forming a second gate layer on an overall surface of the substrate having the first gate layer pattern after the La₂O₃ mask pattern is removed; and
patterning the second gate layer, the first gate layer pattern, and the gate dielectric layer.

5. The method as claimed in claim 4, wherein the second gate layer includes polysilicon, a metal silicide, or a lamination of polysilicon and metal silicide deposited in sequence.

6. The method as claimed in claim 1, wherein the forming of the La₂O₃ mask pattern on the first gate layer disposed on the second region comprises:
forming a La₂O₃ mask layer on the first gate layer disposed on the first region and the second region;
forming a photoresist pattern on the La₂O₃ mask layer to expose the La₂O₃ mask layer disposed on the first region;
selectively removing the La₂O₃ mask layer disposed on the first region by etching, using the photoresist pattern as a mask; and
removing the photoresist pattern.

7. The method as claimed in claim 6, wherein the selective removing of the La₂O₃ mask layer disposed on the first region is performed by dry etching.

8. The method as claimed in claim 1, wherein the gate dielectric layer includes a high-k material.

9. The method as claimed in claim 1, wherein the first gate layer includes a metal, a metal oxide, or a metal nitride.

10. A method of fabricating a semiconductor device, comprising:
forming a gate dielectric layer on an overall surface of a substrate;
forming a gate layer on the gate dielectric layer;
forming a lanthanum-oxide (La₂O₃) mask pattern on the gate layer; and
patterning the gate layer and the gate dielectric layer by etching using the La₂O₃ mask pattern as a mask, thereby forming a gate pattern.

11. The method as claimed in claim 10, further comprising:
removing the La₂O₃ mask pattern, wherein the removing of the La₂O₃ mask pattern is performed by wet etching using a hydrochloric acid (HCl) as an etching solution.

12. The method as claimed in claim 10, wherein the forming of the La₂O₃ mask pattern on the gate layer comprises:
forming a La₂O₃ mask layer on the gate layer;
forming a photoresist pattern on the La₂O₃ mask layer to partially expose the La₂O₃ mask layer;
selectively removing the exposed La₂O₃ mask layer by etching using the photoresist pattern as a mask; and
removing the photoresist pattern.

13. The method as claimed in claim 12, wherein the selective removing of the La₂O₃ mask layer is performed by dry etching.

14. The method as claimed in claim 10, wherein the gate dielectric layer includes a high-k material.

15. The method as claimed in claim 10, wherein the forming of the gate layer comprises:
forming a first gate layer on the gate dielectric layer; and
forming a second gate layer on the first gate layer.

16. The method as claimed in claim 15, wherein the first gate layer includes a metal, a metal oxide, or a metal nitride.

17. The method as claimed in claim 15, wherein the second gate layer includes a polysilicon, a metal silicide, or a lamination of polysilicon and metal silicide deposited in sequence.

18.-20. (canceled)
